(19) United States
(12) Patent Application Publication
(10) Pub. No.: US 2026/0159950 A1
(43) Pub. Date: Jun. 11, 2026

(54) NOTCHED SUSCEPTOR DESIGN FOR STABLE SHADOW FRAME

(71) Applicant: Applied Materials, Inc., Santa Clara, CA (US)

(72) Inventors: Jong Yun Kim, Hwaseong (KR); William Nehrer, Soquel, CA (US); Han Byoul Kim, Suwon (KR); Junpeng Huang, Hefei (CN); Jrjyan Chen, Campbell, CA (US)

(73) Assignee: Applied Materials, Inc., Santa Clara, CA (US)

(21) Appl. No.: 18/706,704

(22) PCT Filed: Nov. 1, 2021
(86) PCT No.: PCT/CN2021/127845

§ 371 Date: May 1, 2024

(51) Int. Cl. C23C 16/458

(52) U.S. Cl. CPC C23C 16/4585

(57) ABSTRACT

Exemplary substrate processing chambers may include a chamber body defining a processing region. The chamber body may include chamber walls. The chambers may include a showerhead disposed atop the chamber body. The chambers may include a susceptor disposed within the chamber body. The support plate may include a substrate receiving surface. A peripheral edge of the susceptor may define a plurality of notches that extend through a thickness of the support plate. The chambers may include a plurality of shadow frame supports extending from the chamber walls. At least some of the plurality of shadow frame supports may include protrusions that extend inward into an interior of the chamber body. Each of the protrusions may be vertically aligned with a respective one of the plurality of notches. The chambers may include a shadow frame that is positionable on the plurality of shadow frame supports.

### TECHNICAL FIELD

The present technology relates to components and apparatuses for glass substrate and semiconductor substrate manufacturing. More specifically, the present technology relates to processing chamber components and other substrate processing equipment.

### BACKGROUND

Liquid crystal displays or flat panels are commonly used for active matrix displays, such as computer, television, and other monitors. Plasma enhanced chemical vapor deposition (PECVD) is used to deposit thin films on a substrate, such as a semiconductor wafer or a transparent substrate for a flat panel display. PECVD is generally accomplished by introducing a precursor gas or gas mixture into a vacuum chamber containing a substrate. The precursor gas or gas mixture is typically directed downwardly through a distribution plate situated near the top of the processing chamber. The precursor gas or gas mixture in the processing chamber is energized (e.g., excited) into a plasma by applying a power, such as a radio frequency (RF) power, to an electrode in the processing chamber from one or more power sources coupled to the electrode. The excited gas or gas mixture reacts to form a layer of material on a surface of the substrate. The layer may be, for example, a passivation layer, a gate insulator, a buffer layer, and/or an etch stop layer. The layer may be a part of a larger structure, such as, for example, a thin film transistor (TFT) or an active matrix organic light emitting diodes (AMOLED) used in a display device.

Flat panels processed by PECVD techniques are typically large. For example, the flat panel may exceed 4 square meters. During processing, the edge and backside of the glass substrate as well as the internal chamber components must be protected from deposition. Typically, a deposition masking device, such as a shadow frame, is placed about the periphery of the substrate to prevent processing gases or plasma from reaching the edge and backside of the substrate and to hold the substrate on a support member during processing. The shadow frame may be positioned in the processing chamber above the support member so that when the support member is moved into a raised processing position, the shadow frame is picked up and contacts an edge portion of the substrate. As a result, the shadow frame covers several millimeters of the periphery of the upper surface of the substrate, thereby preventing edge and backside deposition on the substrate.

In between processing operations, the support member is lowered, with the shadow frame being supported above the support member, such as by a shadow frame support.

Conventional shadow frame supports support the shadow frame outward of the center of gravity of the shadow frame, which may lead to deformation and/or other wear of the shadow frame.

Thus, there is a need for improved systems and methods for supporting shadow frames. These and other needs are addressed by the present technology.

### SUMMARY

Exemplary substrate processing chambers may include a chamber body defining a processing region. The chamber body may include chamber walls. The chambers may include a showerhead disposed atop the chamber body. The chambers may include a susceptor disposed within the chamber body. The susceptor may include a support plate that is coupled with a stem. The support plate may include a substrate receiving surface. A peripheral edge of the susceptor may define a plurality of notches that extend through a thickness of the support plate. The chambers may include a plurality of shadow frame supports extending from the chamber walls. At least some of the plurality of shadow frame supports may include protrusions that extend inward into an interior of the chamber body. Each of the protrusions may be vertically aligned with a respective one of the plurality of notches. The chambers may include a shadow frame that is positionable on the plurality of shadow frame supports.

In some embodiments, the susceptor may be vertically translatable within the processing region between a transfer position and a processing position. In the transfer position, the shadow frame may be supported atop the plurality of shadow frame supports. In the processing position, the shadow frame may be supported atop the peripheral edge of the susceptor. As the susceptor is moved between the transfer position and the processing position, each protrusion may pass through the respective one of the plurality of notches. The shadow frame may include a plurality of side members. Each of the plurality of side members may include a center of gravity. Each of the protrusions may extend inward beyond the center of gravity of the center of gravity of a respective one of the plurality of side members. Each of the plurality of notches may have a width that is at least 2 mm greater than a width of each of the protrusions. Each of the plurality of notches may have a depth that extends at least 1 mm beyond a distal end of a respective protrusion. At least some of the plurality of shadow frame supports may not include a respective protrusion. Each protrusion may include a reinforcement member that extends between a lower surface of the protrusion and a vertical surface of the shadow frame support. The plurality of notches may be disposed at regular intervals about a respective side of the susceptor. Each of the plurality of shadow frame supports may include a generally planar support surface. Each protrusion may extend inward from a respective one of the generally planar surfaces.

Some embodiments of the present technology may encompass susceptors. The susceptors may include a susceptor having a support plate that is coupled with a stem. The support plate may include a substrate receiving surface. A peripheral edge of the susceptor may define a plurality of notches that extend through a thickness of the support plate. Each of the plurality of notches may have a width of at least 5 mm. Each of the plurality of notches may have a depth of at least 10 mm.

In some embodiments, the susceptor may include a plurality of side surfaces. Each of the plurality of side surfaces may define at least one of the plurality of notches. The plurality of notches may be disposed at regular intervals about a respective side of the susceptor. The susceptors may include a chamber body defining a processing region. The chamber body may include chamber walls. The susceptors may include a plurality of shadow frame supports extending from the chamber walls. At least some of the plurality of shadow frame supports may include protrusions that extend inward into an interior of the chamber body. Each of the protrusions may be vertically aligned with a respective one of the plurality of notches. The apparatuses may include a shadow frame that is positionable on the plurality of shadow frame supports. The shadow frame may include a plurality of side members. Each of the plurality of side members may include a center of gravity. Each of the protrusions may extend inward beyond the center of gravity of the center of gravity of a respective one of the plurality of side members. Each of the plurality of shadow frame supports may include a generally planar support surface. Each protrusion may extend inward from a respective one of the generally planar surfaces. Each of the protrusions may include a reinforcement member that extends between a lower surface of the protrusion and a vertical surface of the shadow frame support. Each of the plurality of notches may have a width that is greater than a width of each of the protrusions. Each of the plurality of notches may have a depth that extends beyond a distal end of a respective one of the protrusions.

Some embodiments of the present technology may encompass methods of processing a substrate. The methods may include positioning a substrate on a support plate of a susceptor that is disposed within a processing chamber. The processing chamber may include a chamber body having chamber walls. A peripheral edge of the susceptor may define a plurality of notches that extend through a thickness of the support plate. A plurality of shadow frame supports may extend from the chamber walls. At least some of the plurality of shadow frame supports may include protrusions that extend inward into an interior of the chamber body. Each of the protrusions may be vertically aligned with a respective one of the plurality of notches. The methods may include raising the susceptor to a processing position in which the shadow frame is lifted off of the plurality of shadow frame supports and is seated atop the peripheral edge of the susceptor. The methods may include flowing a precursor into a processing chamber. The methods may include generating a plasma of the precursor within a processing region of the processing chamber. The methods may include depositing a material on the substrate.

In some embodiments, as the susceptor is raised to the processing position, each protrusion may pass through the respective one of the plurality of notches. Each of the plurality of notches may have a width that is greater than a width of each of the protrusions. Each of the plurality of notches may have a depth that extends beyond a distal end of a respective protrusion.

Such technology may provide numerous benefits over conventional systems and techniques. For example, embodiments of the present technology may utilize shadow frame supports that include protrusions that extend beyond a center of gravity of a shadow frame to prevent damage to the shadow frame. Additionally, embodiments may utilize a susceptor that includes notches that enable the susceptor to move above and below the shadow frame supports. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a cross-sectional side elevation view of an exemplary processing system according to some embodiments of the present technology.

FIG. 2 shows a schematic isometric view of an exemplary susceptor according to some embodiments of the present technology.

FIG. 3 shows a schematic top plan view of an exemplary processing chamber according to some embodiments of the present technology.

FIG. 3A shows a schematic isometric view of an exemplary shadow frame support according to some embodiments of the present technology.

FIG. 3B shows a schematic isometric view of an exemplary shadow frame support according to some embodiments of the present technology.

FIGS. 4A and 4B show schematic views of an exemplary processing chamber according to some embodiments of the present technology.

FIG. 5 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

Some processing operations and chambers utilize shadow frames to prevent plasma from being deposited in the edge region of a substrate and/or for other purposes. These shadow frames are typically supported by shadow frame supports when the susceptor is in a transfer position, and are supported by the susceptor itself when the susceptor is raised to a processing position. Conventional shadow frame supports and susceptors enable either the shadow frame supports or the susceptor, but not both, to support a center of gravity of the shadow frame. When the center of gravity of the shadow frame is not sufficiently supported, stresses on the shadow frame may cause the shadow frame to twist and/or otherwise deform over time. Along with needing to replace or repair the shadow frame, the deformation of the shadow frame may cause issues on the substrate. For example, a twisted, lower edge of the shadow frame may touch the substrate first during the raising of the susceptor, which may cause particle generation and subsequent defects on the substrate.

The present technology overcomes these challenges by utilizing shadow frame support and susceptor designs that enable both the shadow frame supports and the susceptor to support a center of gravity of the shadow frame. For example, at least some of the shadow frame supports include a protrusion that extends inward from the chamber walls a sufficient distance to support the center of gravity of the shadow frame when the susceptor is in a transfer position. The susceptor may define a number of notches that are vertically aligned with the protrusions and sized to provide clearance through the susceptor that enables the susceptor to be raised to a processing position. When in the processing position, a peripheral edge of the susceptor (outward of the notches) may support the center of gravity of the shadow frame. In this manner, the center of gravity of the shadow frame may be supported at all times, which may reduce and/or eliminate any deformation of the shadow frame and help to prevent particle generation. Accordingly, the present technology may improve the lifespan of the shadow frame, as well as improve the quality of the processed substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

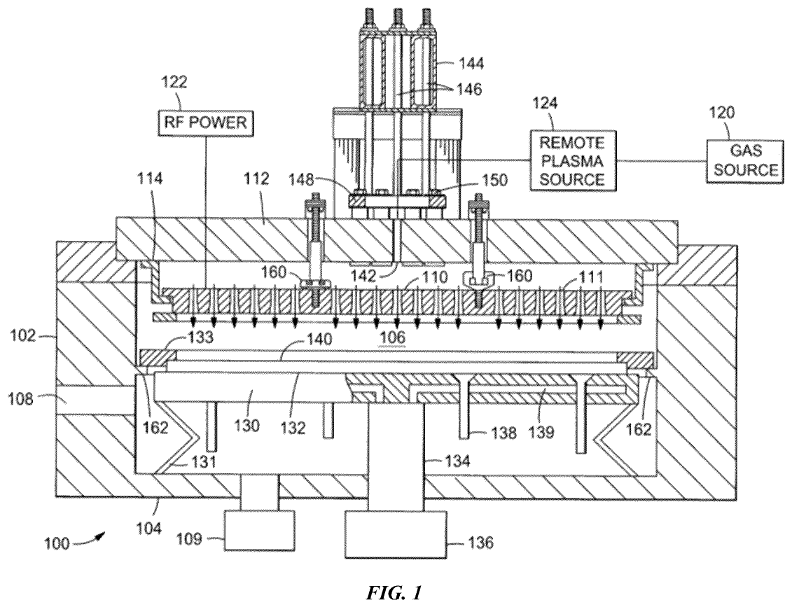

FIG. 1 is a cross sectional side elevation view of a PECVD apparatus according to some embodiments of the present technology. The apparatus may include a vacuum processing chamber 100 in which one or more films may be deposited onto a substrate 140. The apparatus may be used to process one or more substrates, for example, semiconductor substrates, flat panel display substrates, and/or solar panel substrates, among others.

The processing chamber 100 may include chamber walls 102, a bottom 104, and a diffuser or showerhead 110 that define a processing volume 106. A susceptor (or other substrate support) 130 may be disposed in the processing volume 106. The susceptor 130 may include a substrate receiving surface 132 for supporting the substrate 140. The process volume 106 may be accessed through an opening 108 defined through the chamber walls 102 such that the substrate 140 may be transferred in and out of the chamber 100 when the susceptor 130 is in a lowered or transfer position. One or more stems 134 may be coupled to a lift system 136 to translate the susceptor 130 within the chamber 100. As shown in FIG. 1, the substrate is in a lowered position where the substrate 140 can be transferring into and out of the chamber 100. The substrate 140 may be elevated to a processing position for processing. The spacing between the top surface of the substrate 140 disposed on the substrate receiving surface 132 and the showerhead 110 may be between about 400 mil and about 1,200 mil when the susceptor 130 is raised to the processing position. In one embodiment, the spacing may be between about 400 mil and about 800 mil.

Lift pins 138 may be moveably disposed through the susceptor 130 to space the substrate 140 from the substrate receiving surface 132 to facilitate robotic transfer of the substrate 140. The susceptor 130 may also include heating and/or cooling elements 139 to maintain the susceptor 130 at a desired temperature. The susceptor 130 may also include RF return straps 131 to provide a RF return path at the periphery of the susceptor 130.

The showerhead 110 may be coupled to a backing plate 112 at its periphery by a suspension 114. The showerhead 110 may also be coupled to the backing plate 112 by one or more coupling supports 160 to help prevent sag and/or control the straightness/curvature of the showerhead 110.

A gas source 120 may be coupled to the backing plate 112 to provide processing gas through a gas outlet 142 in the backing plate 112 and through gas passages 111 in the showerhead 110 to the substrate 140 disposed on the substrate receiving surface 132. A vacuum pump 109 may be coupled to the chamber 100 to control the pressure within the process volume 106. An RF power source 122 may be coupled to the backing plate 112 and/or to the showerhead 110 to provide RF power to the showerhead 110. The RF power may create an electric field between the showerhead 110 and the susceptor 130 so that a plasma may be generated from the gases between the showerhead 110 and the susceptor 130. Various frequencies may be used, such as a frequency between about 0.3 MHz and about 200 MHz. In one embodiment, the RF power source may be provided at a frequency of 13.56 MHz.

A remote plasma source 124, such as an inductively coupled remote plasma source, may also be coupled between the gas source 120 and the backing plate 112. Between processing substrates, a cleaning gas may be provided to the remote plasma source 124 so that a remote plasma is generated and provided into the processing volume 106 to clean chamber components. The cleaning gas may be further excited while in the processing volume 106 by power applied to the showerhead 110 from the RF power source 122. Suitable cleaning gases include but are not limited to NF3, F2, and SF6.

A frame 133 may be placed adjacent to the periphery region of the substrate 140, either in contact with or spaced from the substrate 140. In some embodiments, the frame 133 may be configured to be disposed under the substrate 140. In other embodiments, the frame 133 may be configured to be disposed over the substrate 140. The frame 133 may be a shadow frame, a non-contact frame (e.g., the frame is not in contact with a substrate when positioned on the susceptor 130), a floating frame, a removable frame, a confinement ring, a flow control structure, or other suitable structure positionable adjacent the periphery of the substrate 140. The frame 133 may have a similar shape as the susceptor 130 in some embodiments. For example, the susceptor 130 and frame 133 may each be rectangular and include multiple sides.

In the embodiment depicted in FIG. 1, the frame 133 may rest on a frame support 162 when the susceptor 130 is lowered to provide clearance for the substrate 140 being placed on or removed from the susceptor 130. In one embodiment, the frame support 162 may include the same material as the chamber walls 102. In another embodiment, the frame support 162 may comprise a conductive material, dielectric material, stainless steel or aluminum. The frame 133 may reduce deposition at the edge of the substrate 140 and on areas of the susceptor 130 that are not covered by the substrate 140. When the susceptor 130 is elevated to the processing position, the frame 133 may engage the substrate 140 and/or susceptor 130, and be lifted off of the frame support 162.

During the cleaning process, the frame 133 may rest on the frame support 162. The substrate receiving surface 132 may also be raised to a level that touches the frame 133 without lifting the frame 133 off from the frame support 162 during cleaning.

The susceptor 130 may have an outer periphery. In some embodiments, the frame 133 or portions thereof, when seated on the susceptor 130, may extend beyond portions of the perimeter of the susceptor 130, and as such, define of the outer profile of the periphery of the susceptor 130. An amount of open area between the susceptor 130 and chamber walls 102 of the processing chamber 100 may control the amount of gas passing by the susceptor 130 and substrate 140 positioned thereon. Thus, by having more open area proximate one region of the susceptor 130 relative to another region, the amount of gas flowing by one region of the susceptor 130 and substrate 140 relative to another may be controlled. For example, the open area proximate a center region of the susceptor 130 may be different than the open area proximate a corner region of the susceptor 130, thus directing more flow through the area with more open area. Directing more flow to one region may be utilized to compensate for other conductance asymmetries to produce a more uniform flow across the substrate, or to cause more gas to flow over one region of the substrate relative another. In one example, flow may be directed to a center region of the susceptor 130 relative to a corner region. In another example, flow may be directed to a corner region of the susceptor 130 relative to a center region. In another example, flow may be directed to one side of the susceptor 130 relative to another side. The open area on a side of the susceptor 130 may be selected by selecting the geometry of the profile of the susceptor 130 to control the width across a gap between the profile of the susceptor 130 and chamber wall 102 of the processing chamber 100, such as the curvature of the perimeter of the susceptor 130 and/or frame 133; and/or selecting a diameter and/or number of apertures formed through the frame 133.

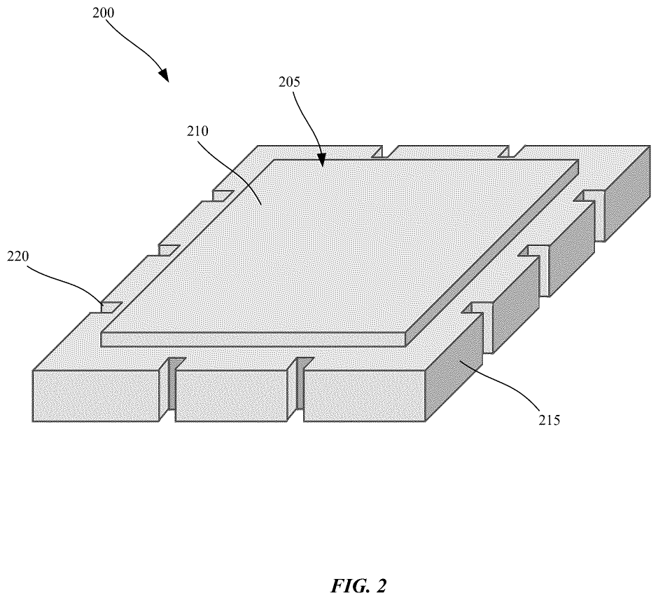

FIG. 2 shows a schematic isometric view of an exemplary susceptor 200 according to some embodiments of the present technology. The susceptor 200 may be included in any chamber or system previously described, as well as any other chamber or system that may benefit from the susceptor 200. For example, the susceptor 200 may be used as susceptor 130 and positioned within the processing chamber 100 as described in relation to FIG. 1. The susceptor 200 may be similar to the susceptor 130 and may include any of the features described in relation to susceptor 130. Susceptor 200 may include a support plate 205 and a stem (not shown) coupled with a bottom surface of the support plate 205. As illustrated, the support plate 205 has a generally rectangular shape, although the support plate 205 may have any other shape in various embodiments, such as circular and/or elliptical. The support plate 205 may include a substrate receiving surface 210 (similar to substrate receiving surface 132), which may be sized and shaped to support a substrate, such as substrate 140, which may be a semiconductor wafer, a transparent substrate (such as glass) for a flat panel display, and/or other substrate. In some embodiments, the substrate receiving surface 210 may be raised relative to a peripheral edge 215 of the support plate 205, while in other embodiments, the substrate receiving surface 210 may be coplanar with and/or recessed relative to the peripheral edge 215.

The peripheral edge 215 may define a plurality of notches 220 that extend through a thickness of the support plate 205. The notches 220 may be provided at regular and/or irregular intervals about one or more sides of the peripheral edge 215 of the susceptor 200. Each side of the support plate 205 may have a same or different number of notches 220, while in other embodiments, the different sides may have different numbers of notches 220 (or possibly no notches). In the illustrated embodiments, the support plate 205 includes two short sides, with each short side defining two notches 220. Support plate 205 includes two longer sides, with each longer side defining three notches 220. Each side of the support plate 205 may include at least or about one notch 220, at least or about two notches 220, at least or about three notches 220, at least or about four notches 220, at least or about five notches 220, at least or about six notches 220, or more. A size and/or number of notches 220 provided on the support plate 205 may be selected to limit temperature distribution about the support plate 205, with smaller numbers and/or sizes of notches 220 leading to improved temperature uniformity across the support plate 205. In some embodiments, each notch 220 may have a width of between or about 5 mm and 50 mm, between or about 10 mm and 40 mm, or between or about 20 mm and 30 mm. A depth (e.g., distance from the peripheral edge 215) of each notch 220 may be between or about 10 mm and 75 mm, between or about 20 mm and 60 mm, or between or about 30 mm and 50 mm.

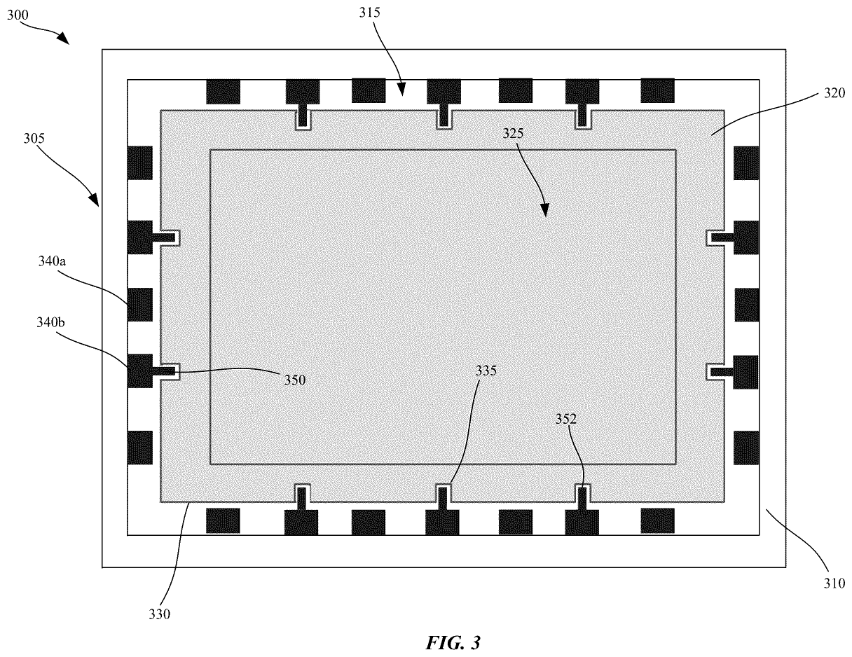

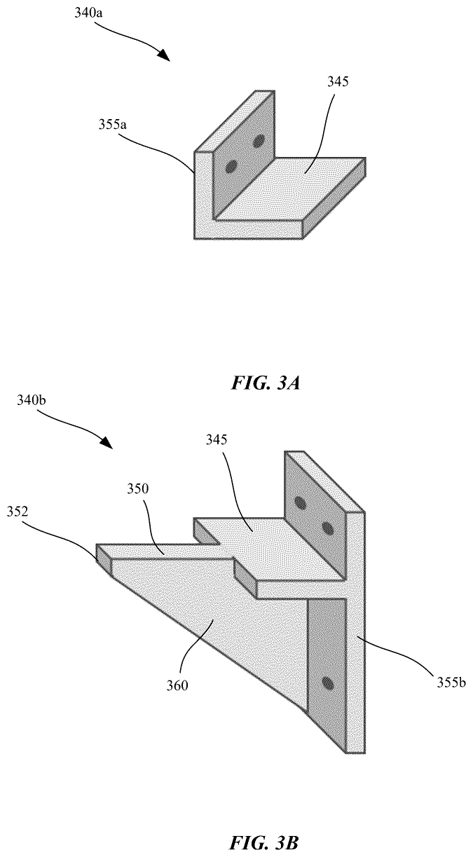

FIG. 3 illustrates a schematic top plan view of a processing chamber 300 according to some embodiments of the present technology. Chamber 300 may be similar to the chamber 100 and may include any of the features described in relation to chamber 100. For example, chamber 300 may include a chamber body 305 that includes a number of chamber walls 310. A susceptor 315 may be disposed within the chamber body 305. Susceptor 315 may be similar to susceptors 130 and 200 described herein and may include any of the features described in relation to susceptors 130 and 200. For example, the susceptor 315 may include a support plate 320 coupled with a stem (not shown). The support plate 320 may include a substrate receiving surface 325 that is at least partially surrounded by a peripheral edge 330 of the support plate 320. The peripheral edge 330 may define a number of notches 335 on some or all sides of the support plate 320.

Chamber 300 may include a number of shadow frame supports 340 that extend inward from the chamber walls 310. The shadow frame supports 340 may be spaced along some or all of the chamber walls 310 at regular and/or irregular intervals. The shadow frame supports 340 may be positioned above the susceptor 315 to support a shadow frame (not shown) when the susceptor 315 is in a transfer position. For example, each shadow frame support 340 may include a generally planar support surface 345, which may be used to support a bottom surface of the shadow frame (or other frame). Each support surface 345 may be positioned outward of the peripheral edge 330 of the support plate 320, which may enable the susceptor 315 to translate between the transfer position (in which the susceptor 315 is lower than the shadow frame supports 340) and a processing position (in which the susceptor 315 is higher than the shadow frame supports 340).

At least some of the shadow frame supports 340 may include protrusions 350 that extend inward into an interior of the chamber body 305 from the support surface 340. For example, chamber 300 may include a number of shadow frame supports 340a that do not include protrusions 350 and a number of shadow frame supports 340b that include protrusions 350. In some embodiments, chamber 300 may include only shadow frame supports 340b. FIG. 3A illustrates a schematic isometric view of a shadow frame support 340a. For example, each shadow frame support 340a may include a vertical member 355a that may be used to fasten and/or otherwise couple the shadow frame support 340a with a chamber wall 310. The support surface 345 may extend inward from the vertical member 355a. As illustrated, the support surface 345 extends from a bottom edge of the vertical member 355a, however the support surface 345 may extend from a medial region and/or top edge of the vertical member 355a in some embodiments.

FIG. 3B illustrates a schematic isometric view of a shadow frame support 340b. Each shadow frame support 340b may include a vertical member 355b that may be used to fasten and/or otherwise couple the shadow frame support 340b with a chamber wall 310. The support surface 345 may extend inward from the vertical member 355b. As illustrated, the support surface 345 extends from a medial region of the vertical member 355a, however the support surface 345 may extend from a bottom edge and/or top edge of the vertical member 355b in some embodiments. Each shadow frame support 340b includes a protrusion 350 that extends inward from the support surface 345. A length of each protrusion 350 is sufficient to position a distal end 352 of the protrusion 350 inward of a center of gravity of a respective side of a shadow frame that is supported atop the shadow frame support 340b when the susceptor 315 is in a transfer position. For example, a distal end 352 of each protrusion 350 may extend at least or about 5 mm inward beyond the peripheral edge 330 of the susceptor 315, at least or about 10 mm, at least or about 15 mm, at least or about 20 mm, at least or about 25 mm, at least or about 30 mm, at least or about 35 mm, at least or about 40 mm, or more. Each of the protrusions 350 may have a width of at least or about 3 mm, at least or about 5 mm, at least or about 8 mm, at least or about 10 mm, at least or about 12 mm, at least or about 15 mm, at least or about 18 mm, at least or about 20 mm, or more. In some embodiments, the shadow frame support 340 b may omit the support surface 345 such that the protrusion 350 extends from the vertical member 355b.

The shadow frame support 340b may include a reinforcement member 360, which may further strengthen the protrusion 350. As illustrated, the reinforcement member 360 extends from a lower edge of the vertical member 355b and extends at an angle to the distal end of the protrusion 350. In other embodiments, the reinforcement member 360 may extend from a medial region (from above and/or below the protrusion 350) and/or top edge of the vertical member 355b. The reinforcement member 360 may extend along all or a portion of the length of the protrusion 350. While shown as being a solid member that fills an entire space between the protrusion 350, support surface 340, and vertical member 355b, the reinforcement member 360 may define one or more openings in some embodiments. Additionally, while shown with an edge of the reinforcement member 360 being linear, nonlinear reinforcement members may be utilized in various embodiments.

Turning back to FIG. 3, each shadow frame support 340b may be aligned with a respective notch 335 with a distal end of each protrusion 350 being in vertical alignment with the respective notch 335. Each notch 335 may be slightly larger than the protrusion 350 such that as the susceptor 315 is raised and lowered within the chamber 300, each protrusion 350 passes through a respective one of the notches 335 without contacting the susceptor 315. For example, each notch 335 may have a width that is greater than a width of each of the protrusions 350 and a depth that extends beyond a distal end of the respective protrusion 350. In some embodiments, a width of each notch 335 may be greater than a width of each protrusion 350 by at least or about 2 mm, at least or about 4 mm, at least or about 6 mm, at least or about 8 mm, at least or about 10 mm, at least or about 12 mm, or more. For example, the width of each notch 335 may be at least or about 5 mm, at least or about 7 mm, at least or about 10 mm, at least or about 12 mm, at least or about 14 mm, at least or about 17 mm, at least or about 20 mm, at least or about 22 mm, or more. In some embodiments, a depth of each notch 335 may extend at least or about 1 mm beyond a distal end of a respective protrusion, at least or about 2 mm, at least or about 3 mm, at least or about 4 mm, at least or about 5 mm, at least or about 6 mm, at least or about 7 mm, at least or about 8 mm, at least or about 9 mm, at least or about 10 mm, or more. For example, a depth of each notch 335 may be at least or about 6 mm, at least or about 8 mm, at least or about 10 mm, at least or about 12 mm, at least or about 14 mm, at least or about 16 mm, at least or about 18 mm, at least or about 20 mm, at least or about 25 mm, at least or about 30 mm, or more.

As illustrated, shadow frame supports 340a and 340b are arranged in an alternating fashion about the susceptor 315, however any other arrangement of shadow frame supports 340 are possible in various embodiments. For example, one shadow frame support 340b may be provided for every two, three, etc. shadow frame supports 340a. In other embodiments, shadow frame supports 340b may outnumber shadow frame supports 340a. The shadow frame supports 340 may be arranged in a symmetric or asymmetric pattern about the susceptor 315.

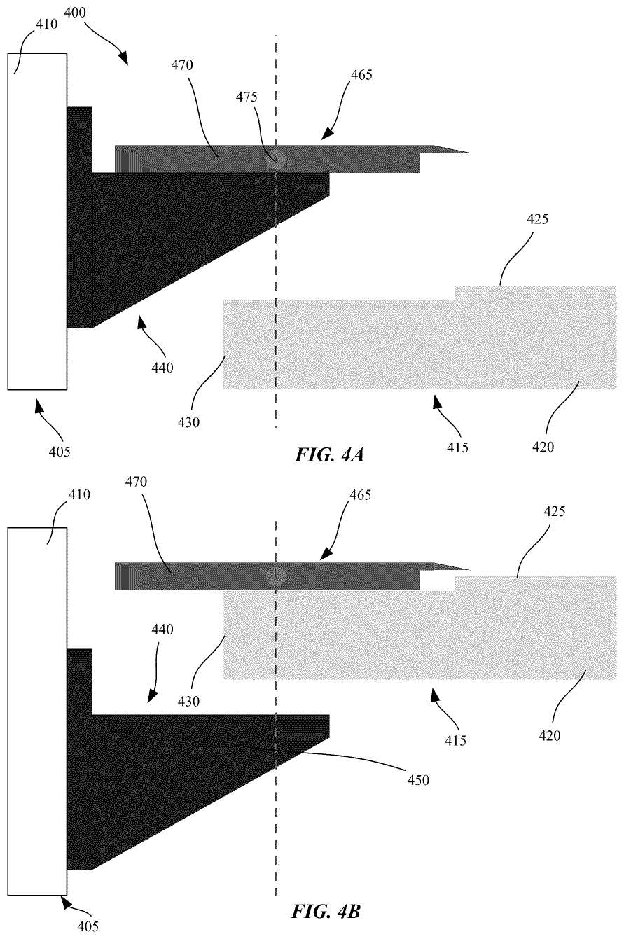

FIGS. 4A and 4B illustrate partial cross-sectional side elevation views of a processing chamber 400 according to some embodiments of the present technology. Chamber 400 may be similar to the chambers 100 and 300 and may include any of the features described in relation to chambers 100 and 300. For example, chamber 400 may include a chamber body 405 that includes a number of chamber walls 410. A susceptor 415 may be disposed within the chamber body 405. Susceptor 415 may be similar to susceptors 130, 200, and 315 described herein and may include any of the features described in relation to susceptors 130, 200, and 315. For example, the susceptor 415 may include a support plate 420 coupled with a stem (not shown).

The support plate 420 may include a substrate receiving surface 425 that is at least partially surrounded by a peripheral edge 430 of the support plate 420. The peripheral edge 430 may define a number of notches (not shown) on some or all sides of the support plate 420.

A number of shadow frame supports 440 may be provided that extend inward from the chamber walls 310. While shown with shadow frame supports 440 including protrusions 450, it will be appreciated that some of the shadow frame supports 440 may not include protrusions 450. A shadow frame 465 may be seated atop the shadow frame supports 440 when the susceptor 315 is in a lower transfer position, as illustrated in FIG. 4A. In some embodiments, the shadow frame 465 may include a number of different side members 470 that are coupled with one another, such as by using pins and/or other fastening mechanisms. Each side member 470 may include a center of gravity 475, which is located within a medial region of the side member 470. The protrusion 450 may extend inward beyond the center of gravity 475 such that the shadow frame support 440 supports the side member 470 inward, at, and outward of the center of gravity 475. By supporting the center of gravity 475 of the side member 470 of the shadow frame 465, the shadow frame supports 440 may provide adequate support to maintain the shadow frame 465 in a desired position, while also preventing the shadow frame 465 from twisting and/or otherwise deforming. As noted above, some of the shadow frame supports 440 may not include protrusions 450 (and may be similar to shadow frame supports 340a) and may instead be positioned entirely outward of the peripheral edge 430 of the susceptor 415. The use of such shadow frame supports 440 may provide further support for a peripheral edge of the shadow frame 465 without increasing the number of notches provided in the susceptor 415 to provide clearance for protrusions 450. Reducing the number of notches may improve the temperature uniformity across the susceptor 415.

As the susceptor 415 is translated upward into the processing position, the protrusions 450 pass through the notches formed in the susceptor 415 and enable the susceptor 415 to be raised above the shadow frame supports 440. The peripheral edge 430 of the susceptor 415 may contact an underside of the shadow frame 465 and lift the shadow frame 465 off of the shadow frame supports 440 as illustrated in FIG. 4B. The peripheral edge 430 of the susceptor 415 may support the shadow frame 465, with the peripheral edge 430 extending outward of the center of gravity 475 of each side member 470 such that the center of gravity of the side members 470 of the shadow frame 465 are supported by the susceptor 415. Such positioning may help ensure that the shadow frame 465 will not twist and/or otherwise deform when carried by the susceptor 415.

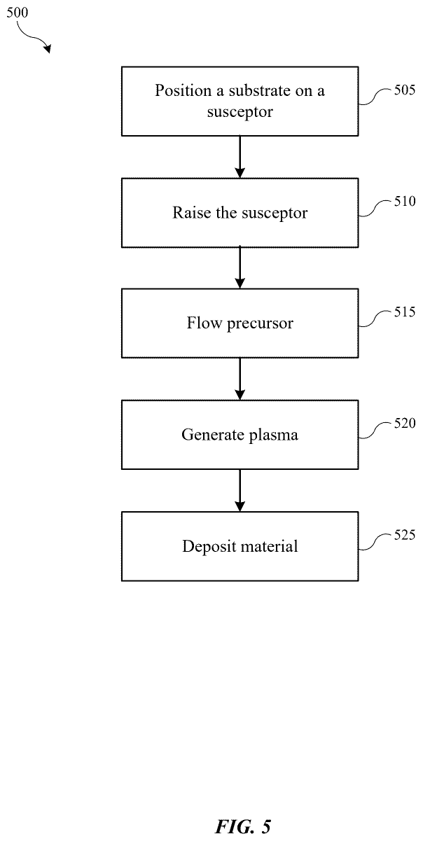

FIG. 5 illustrates operations of an exemplary method 500 of semiconductor processing according to some embodiments of the present technology. The method may be performed in a variety of processing chambers, including chamber 100, 300, and 400 described above, which may include shadow frame supports and/or susceptors according to embodiments of the present technology, such as shadow frame supports 162, 340, and 440 and/or susceptors 130, 200, 315, and 415. Method 500 may include a number of optional operations, which may or may not be specifically associated with some embodiments of methods according to the present technology.

Method 500 may include a processing method that may include operations for forming a hardmask film or other deposition operations. The method may include optional operations prior to initiation of method 500, or the method may include additional operations. For example, method 500 may include operations performed in different orders than illustrated. Method 500 may include positioning a substrate on a support plate of a susceptor that is disposed within a processing chamber at operation 505. For example, the substrate may be positioned on a substrate receiving surface of the susceptor. An outer periphery of the susceptor may define a plurality of notches that extend through a thickness of the support plate. A number of shadow frame supports may extend from the chamber walls, with at least some of the shadow frame supports including protrusions that extend inward into an interior of the chamber body. Each of the protrusions may be vertically aligned with a respective one of the plurality of notches. At operation 510, the method 500 may include raising the susceptor to a processing position in which the shadow frame is lifted off of the plurality of shadow frame supports and is seated atop a peripheral edge of the susceptor. As the susceptor is raised to the processing position, each protrusion may pass through the respective one of the plurality of notches.

In some embodiments, method 500 may include flowing one or more precursors or other process gases into a processing chamber at operation 515. For example, the precursor may be flowed into a chamber, such as chamber 100, 300, or 400, and may flow the precursor through one or more of a gasbox, a blocker plate, or a faceplate, prior to delivering the precursor into a processing region of the chamber. At operation 520, a plasma may be generated of the precursors within the processing region, such as by providing RF power to the faceplate to generate a plasma. Material formed in the plasma may be deposited on the substrate at operation 525.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate processing chamber, comprising:
a chamber body defining a processing region, the chamber body comprising chamber walls;
a showerhead disposed atop the chamber body;
a susceptor disposed within the chamber body, wherein:
the susceptor comprises a support plate that is coupled with a stem;
the support plate comprises a substrate receiving surface; and
a peripheral edge of the susceptor defines a plurality of notches that extend through a thickness of the support plate;
a plurality of shadow frame supports extending from the chamber walls, wherein:
at least some of the plurality of shadow frame supports comprise protrusions that extend inward into an interior of the chamber body; and
each of the protrusions is vertically aligned with a respective one of the plurality of notches; and
a shadow frame that is positionable on the plurality of shadow frame supports.

2. The substrate processing chamber of claim 1, wherein:
the susceptor is vertically translatable within the processing region between a transfer position and a processing position;
in the transfer position, the shadow frame is supported atop the plurality of shadow frame supports; and
in the processing position, the shadow frame is supported atop the peripheral edge of the susceptor.

3. The substrate processing chamber of claim 2, wherein:
as the susceptor is moved between the transfer position and the processing position, each protrusion passes through the respective one of the plurality of notches.

4. The substrate processing chamber of claim 1, wherein:
the shadow frame comprises a plurality of side members, each of the plurality of side members comprising a center of gravity; and
each of the protrusions extends inward beyond the center of gravity of the center of gravity of a respective one of the plurality of side members.

5. The substrate processing chamber of claim 1, wherein:
each of the plurality of notches has a width that is at least 2 mm greater than a width of each of the protrusions; and
each of the plurality of notches has a depth that extends at least 1 mm beyond a distal end of a respective protrusion.

6. The substrate processing chamber of claim 1, wherein:
at least some of the plurality of shadow frame supports do not include a respective protrusion.

7. The substrate processing chamber of claim 1, wherein:
each protrusion comprises a reinforcement member that extends between a lower surface of the protrusion and a vertical surface of the shadow frame support.

8. The substrate processing chamber of claim 1, wherein:
the plurality of notches are disposed at regular intervals about a respective side of the susceptor.

9. The substrate processing chamber of claim 1, wherein:
each of the plurality of shadow frame supports comprising a generally planar support surface; and
each protrusion extends inward from a respective one of the generally planar surfaces.

10. A susceptor, comprising:
a susceptor comprising a support plate that is coupled with a stem, wherein:
the support plate comprises a substrate receiving surface; and
a peripheral edge of the susceptor defines a plurality of notches that extend through a thickness of the support plate;
each of the plurality of notches has a width of at least 5 mm; and
each of the plurality of notches has a depth of at least 10 mm.

11. The susceptor of claim 10, wherein:
the susceptor comprises a plurality of side surfaces; and
each of the plurality of side surfaces defines at least one of the plurality of notches.

12. The susceptor of claim 10, wherein:
the plurality of notches are disposed at regular intervals about a respective side of the susceptor.

13. The susceptor of claim 10, further comprising:
a chamber body defining a processing region, the chamber body comprising chamber walls;
a plurality of shadow frame supports extending from the chamber walls, wherein:
at least some of the plurality of shadow frame supports comprise protrusions that extend inward into an interior of the chamber body; and
each of the protrusions is vertically aligned with a respective one of the plurality of notches; and
a shadow frame that is positionable on the plurality of shadow frame supports.

14. The susceptor of claim 13, wherein:
the shadow frame comprises a plurality of side members, each of the plurality of side members comprising a center of gravity; and
each of the protrusions extends inward beyond the center of gravity of the center of gravity of a respective one of the plurality of side members.

15. The susceptor of claim 13, wherein:
each of the plurality of shadow frame supports comprising a generally planar support surface; and
each protrusion extends inward from a respective one of the generally planar surfaces.

16. The susceptor of claim 13, wherein:
each of the protrusions comprises a reinforcement member that extends between a lower surface of the protrusion and a vertical surface of the shadow frame support.

17. The susceptor of claim 13, wherein:
each of the plurality of notches has a width that is greater than a width of each of the protrusions; and
each of the plurality of notches has a depth that extends beyond a distal end of a respective one of the protrusions.

18. A method of processing a substrate, comprising:
positioning a substrate on a support plate of a susceptor that is disposed within a processing chamber, wherein:
the processing chamber comprises a chamber body having chamber walls;
a peripheral edge of the susceptor defines a plurality of notches that extend through a thickness of the support plate;
a plurality of shadow frame supports extend from the chamber walls;
at least some of the plurality of shadow frame supports comprise protrusions that extend inward into an interior of the chamber body; and
each of the protrusions is vertically aligned with a respective one of the plurality of notches; and
raising the susceptor to a processing position in which the shadow frame is lifted off of the plurality of shadow frame supports and is seated atop the peripheral edge of the susceptor;
flowing a precursor into a processing chamber;
generating a plasma of the precursor within a processing region of the processing chamber; and
depositing a material on the substrate.

19. The method of processing a substrate of claim 18, wherein:
as the susceptor is raised to the processing position, each protrusion passes through the respective one of the plurality of notches.

20. The method of processing a substrate of claim 18, wherein:
each of the plurality of notches has a width that is greater than a width of each of the protrusions; and
each of the plurality of notches has a depth that extends beyond a distal end of a respective protrusion.
